(19) United States
(12) Patent Application Publication
(10) Pub. No.: US 2025/0393144 A1
(43) Pub. Date: Dec. 25, 2025

(54) FOLDABLE DISPLAY PANEL AND FOLDABLE DISPLAY DEVICE

(71) Applicant: Xiamen Tianma Display Technology Co., Ltd., Xiamen (CN)

(72) Inventors: Wenshuo LIN, Xiamen (CN); Zhipeng YANG, Xiamen (CN); Wenzhi LI, Xiamen (CN); Huifang ZHOU, Xiamen (CN); Haocheng WANG, Xiamen (CN)

(73) Assignee: Xiamen Tianma Display Technology Co., Ltd., Xiamen (CN)

(21) Appl. No.: 18/894,031

(22) Filed: Sep. 24, 2024

(30) Foreign Application Priority Data
Jun. 21, 2024 (CN) 202410813783.9

(51) Int. Cl. H05K 5/02

(52) U.S. Cl. CPC H05K 5/0217

(57) ABSTRACT

The present application relates to a foldable display panel and a foldable display device. The foldable display panel has a bending area and includes a display substrate, and a touch lead wire is arranged on one side of the display substrate and includes a first touch lead wire and a second touch lead wire, and the second touch lead wire is located on a side of the first touch lead wire away from the display substrate. A thickness of the second touch lead wire along a thickness direction of the display substrate is greater than a thickness of the first touch lead wire along the thickness direction of the display substrate. In at least part of the bending area, an orthographic projection of the first touch lead wire on the display substrate is located within an orthographic projection of the second touch lead wire on the display substrate.

### CROSS-REFERENCE TO RELATED APPLICATIONS

This application claims priority to Chinese Patent Application No. 202410813783.9, titled “FOLDABLE DISPLAY PANEL AND FOLDABLE DISPLAY DEVICE” and filed on Jun. 21, 2024, which is hereby incorporated by reference in its entirety.

### TECHNICAL FIELD

The present application relates to the field of display technology, and in particular to a foldable display panel and a foldable display device.

### BACKGROUND

With the continuous development of display technology, people have put forward higher requirements for display devices. They hope to have a large screen and a wide field of view when in use, and also hope to have good portability when not in use. In order to meet this demand, foldable display devices have been launched in batches, becoming a typical representative of both large screen and portability.

However, during the folding process of the above-mentioned foldable display device, the touch lead wire arranged in the border area is prone to fracture.

### SUMMARY

Based on this, it is necessary to provide a foldable display panel and a foldable display device, aiming to solve the problem that the touch lead wire is prone to fracture.

In the first aspect, an embodiment of the present application provides a foldable display panel, which has a first bending area and comprises a display substrate, a touch lead wire is provided on a side of the display substrate and includes a first touch lead wire and a second touch lead wire that are arranged in a stacked manner. The second touch lead wire is located on a side of the first touch lead wire away from the display substrate, a thickness of the second touch lead wire along a thickness direction of the display substrate is greater than a thickness of the first touch lead wire along the thickness direction of the display substrate; in at least part of the first bending area, an orthographic projection of the first touch lead wire on the display substrate is located within an orthographic projection of the second touch lead wire on the display substrate.

In the foldable display panel provided by the embodiments of the present application, in at least part of the first bending area, an edge of the orthographic projection of the second touch lead wire on the display substrate is located outside the orthographic projection of the first touch lead wire on the display substrate, so that the edge of the second touch lead wire and the first touch lead wire are not arranged directly opposite each other along the thickness direction of the display substrate. After the foldable display panel is folded, in at least part of the first bending area, the edge of the second touch lead wire may not generate a force on the first touch lead wire, and the non-edge part of the second touch lead wire exerts a relatively uniform force on the first touch lead wire, thereby alleviating the fracture condition of the first touch lead wire.

In a second aspect, an embodiment of the present application provides a foldable display device, including the above-mentioned foldable display panel in the first aspect.

The foldable display device provided by the embodiments of the present application includes a foldable display panel, in at least part of the first bending area, an edge of the orthographic projection of the second touch lead wire on the display substrate is located outside the orthographic projection of the first touch lead wire on the display substrate, so that the edge of the second touch lead wire and the first touch lead wire are not arranged directly opposite each other along the thickness direction of the display substrate. After the foldable display panel is folded, in at least part of the first bending area, the edge of the second touch lead wire may not generate a force on the first touch lead wire, and the non-edge part of the second touch lead wire exerts a relatively uniform force on the first touch lead wire, thereby alleviating the fracture condition of the first touch lead wire.

### BRIEF DESCRIPTION OF THE DRAWINGS

FIG. 1 is a top view of a foldable display panel provided in an embodiment of the present application.

FIG. 2 is a partial top view of a first touch lead wire, a second touch lead wire and a display substrate in a first bending area provided in an embodiment of the present application.

FIG. 3 is a cross-sectional view of FIG. 2 along an A-A direction.

FIG. 4A is a partial cross-sectional view of a first touch lead wire, a second touch lead wire and a display substrate in a non-bending area provided in an embodiment of the present application.

FIG. 4B is another partial cross-sectional view of the first touch lead wire, the second touch lead wire and the display substrate in the non-bending area provided in an embodiment of the present application.

FIG. 5 is a partial top view of a first touch lead wire, a second touch lead wire and a display substrate in a first display area provided in an embodiment of the present application.

FIG. 6 is an enlarged structural schematic diagram of part E in FIG. 5.

FIG. 7 is a cross-sectional view of FIG. 6 along a B-B direction.

FIG. 8 is a cross-sectional view of FIG. 6 along a C-C direction.

FIG. 9 is an enlarged structural schematic diagram of part F in FIG. 5.

FIG. 10 is a partial top view of a first touch lead wire, a second touch lead wire and a conductive member in a first sub-non-display area provided in an embodiment of the present application.

FIG. 11 is a cross-sectional view of FIG. 10 along a D-D direction.

FIG. 12 is a cross-sectional electron microscope scanning diagram of the first sub-non-display area.

FIG. 13 is a cross-sectional electron microscope scanning diagram of the first sub-non-display area provided in the embodiment of the present application.

### REFERENCE NUMERALS

100, foldable display panel; 101a, first bending area; 101b, first display area; 101c, first non-display area; 1011, first boundary; 1012, second boundary; 102a, second bending area; 100d, non-bending area; 101d, first non-bending area; 102d, second non-bending area; 102b, second display area; 102c, second non-display area; 1021c, first sub-non-display area; 1022c, second sub-non-display area; 110, first touch lead wire; 111, first portion section; 1111, first side; 1112, second side; 113, third portion section; 115, fifth portion section; 1155, fifth side; 1156, sixth side; 117, seventh portion section; 119, ninth portion section; 120, second touch lead wire; 122, second portion section; 1223, third side; 1224, fourth side; 124, fourth portion section; 126, sixth portion section; 1267, seventh side; 1268, eighth side; 128, eighth portion section; 1281, first sub-portion section; 1282, second sub-portion section; 1210, tenth portion section; 130, display substrate; 141, first insulating layer; 142, second insulating layer; 151, first via; 152, second via; 153, third via; 154, fourth via; 160, conductive member.

### DETAILED DESCRIPTION

In order to facilitate the understanding of the present application, the present application will be described more comprehensively below with reference to the relevant drawings. The preferred embodiments of the present application are given in the drawings. However, the present application can be implemented in many different forms and is not limited to the embodiments described herein. On the contrary, the purpose of providing these embodiments is to make the understanding of the disclosure of the present application more thorough and comprehensive.

Unless otherwise defined, all technical and scientific terms used herein have the same meaning as those generally understood by technicians in the technical field of the present application. The terms used in the specification of the present application are only for the purpose of describing specific embodiments and are not intended to limit the present application. The term “and/or” used herein includes any and all combinations of one or more related listed items.

When describing the positional relationship, unless otherwise specified, when an element such as a layer, film or substrate is referred to as being “on” another element, it can be directly on the other element or there can also be an intermediate element. Further, when a layer is referred to as being “under” another layer, it can be directly below or there can be one or more light-emitting units. It is also understood that when a layer is referred to as being “between” two layers, it may be the only layer between the two layers, or there may be one or more light-emitting units.

In the case of using “including”, “having”, and “comprising” described herein, another component may be added unless a clear limiting term, such as “only”, “consisting of”, etc., is used. Unless otherwise mentioned, a term in the singular form may include a plural form and is not to be understood as one in number.

It should be understood that although the terms “first”, “second”, etc. may be used herein to describe various elements, these elements should not be limited by these terms. These terms are only used to distinguish one element from another element. For example, a first element may be referred to as a second element, and similarly, a second element may be referred to as a first element without departing from the scope of the present application.

It should also be understood that when interpreting an element, although not explicitly described, the element is interpreted as including an error range, which should be within the acceptable deviation range of a specific value determined by those skilled in the art. For example, “about”, “approximately” or “substantially” may mean within one or more standard deviations, which are not limited here.

In addition, in the specification, the phrase “planar distribution diagram” refers to a figure when the target part is observed from above, and the phrase “cross-sectional diagram” refers to a figure when a cross section cut by vertically cutting the target part is observed from the side surface.

In addition, the figures are not drawn in a 1:1 ratio, and the relative sizes of the components are drawn in the figures only as examples, and not necessarily in true proportion.

In the related art, a foldable display panel includes a bending area and a non-bending area located on both sides of the bending area. In the bending area, the display panel may include a first touch lead wire and a second touch lead wire disposed on one side of the substrate, and the second touch lead wire is located on one side of the first touch lead wire away from the substrate, where a width of the first touch lead wire is equal to a width of the second touch lead wire, and a thickness of the second touch lead wire is greater than a thickness of the first touch lead wire. When the foldable display panel is in a folded state, the first touch lead wire and the second touch lead wire are greatly deformed, and the first touch lead wire itself has a small thickness, so that the first touch lead wire becomes thinner after bending, resulting in the first touch lead wire being more likely to fracture if subjected to a large stress.

However, since the width of the first touch lead wire is equal to the width of the second touch lead wire, and there are errors in the preparation process, the overlapping parts of the first touch lead wire and the second touch lead wire along the thickness direction of the substrate cannot overlap completely, and an edge of the orthographic projection of the second touch lead wire on the substrate may be located within the orthographic projection of the first touch lead wire on the substrate, so that the edge of the second touch lead wire and a middle portion of the first touch lead wire are arranged directly opposite each other along the thickness direction of the substrate. When the foldable display panel is in a folded state, the edge of the second touch lead wire directly opposite to the middle portion of the first touch lead wire will generate a relatively large force on the first touch lead wire (because the force is a linear force), and the stress generated by the edge of the second touch lead wire on the first touch lead wire is relatively concentrated, thereby causing the thinner first touch lead wire to fracture under the action of the edge of the second touch lead wire.

Based on the above technical problems, the inventors have found that the present application provides a foldable display panel and a foldable display device. In at least part of the first bending area, an orthographic projection of the first touch lead wire on the display substrate is located within an orthographic projection of the second touch lead wire on the display substrate. In this way, in at least part of the first bending area, an edge of the orthographic projection of the second touch lead wire on the display substrate is located outside the orthographic projection of the first touch lead wire on the display substrate, so that the edge of the second touch lead wire and the first touch lead wire are not arranged directly opposite each other along the thickness direction of the display substrate. After the foldable display panel is folded, in at least part of the first bending area, the edge of the second touch lead wire may not generate a force on the first touch lead wire, and the non-edge part of the second touch lead wire exerts a relatively uniform force on the first touch lead wire (the force is a surface force), thereby alleviating the fracture condition of the first touch lead wire.

The above is the core idea of the present application. The technical scheme in the embodiments of the present application will be clearly and completely described below in conjunction with the drawings in the embodiments of the present application. Based on the embodiments in the present application, all other embodiments obtained by those skilled in the art without creative work belong to the scope of protection of the present application.

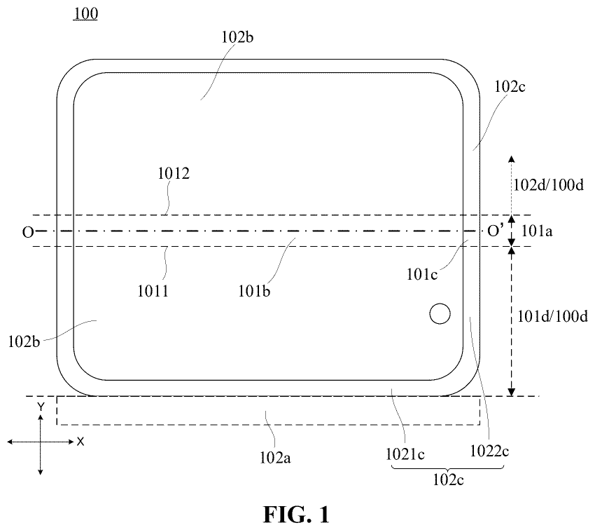

The foldable display device provided in the embodiments of the present application will be described below in conjunction with FIGS. 1 to 13.

The present embodiment provides a foldable display device, which may include a foldable display panel 100. The foldable display device may be a mobile phone or any electronic product with a display function, including but not limited to the following categories: televisions, laptops, desktop displays, tablet computers, digital cameras, smart bracelets, smart glasses, vehicle displays, industrial control equipment, medical display screens, touch interactive terminals, etc., which are not specifically limited in the embodiments of the present application.

In some embodiments, the foldable display panel 100 may include an organic light emitting diode display panel (Organic Light Emitting Diode, referred to as OLED), a quantum dot electroluminescent display panel (Quantum Dot Light Emitting Diodes, referred to as QLED), a sub-millimeter light emitting diode display (Mini Light Emitting Diode Display, referred to as Mini LED) or a micro light emitting diode display (Micro Light Emitting Diode Display, referred to as Micro LED), etc. The embodiments of the present application take the foldable display panel 100 as an OLED display panel as an example for description.

For example, the foldable display panel 100 can be applied to large curvature quadrilateral, hyperbolic and other screens.

Referring to FIG. 1, the foldable display panel 100 may have a first direction X, a second direction Y and a third direction that are all different. The first direction X and the second direction Y may be any two different directions parallel to the foldable display panel 100, and the third direction may be any direction intersecting with a plane parallel to the foldable display panel 100. For example, the first direction X, the second direction Y and the third direction may be perpendicular to each other. Exemplarily, the first direction X may be a length direction of the foldable display panel 100, the second direction Y may be a width direction of the foldable display panel 100, and the third direction may be a thickness direction of the foldable display panel 100. The length, width and thickness, etc. in the embodiments of the present application are only for the convenience of description and do not mean any limitation on the size. For example, the width may be greater than, equal to or less than the length.

In some embodiments, referring to FIG. 1, the foldable display panel 100 may include a first bending area 101a and a non-bending area 100d that are arranged adjacent to each other. For example, the first bending area 101a and the non-bending area 100d may be arranged adjacent to each other along the second direction Y. The number of the first bending area 101a and the non-bending area 100d each is at least one, and one first bending area 101a and one non-bending area 100d are alternately arranged.

For example, the number of the first bending area 101a may be 1, 2, 3 or any number greater than 3. The number of the non-bending area 100d may be 1, 2, 3 or any number greater than 3.

The embodiment of the present application is described by taking an example that the number of the first bending area 101a is one, the number of the non-bending area 100d is two, and the two non-bending areas 100d are connected by the first bending area 101a.

Exemplarily, referring to FIG. 1, the first bending area 101a may have a first boundary 1011 and a second boundary 1012 spaced apart along the second direction Y. A distance between the first boundary 1011 and the second boundary 1012 may be greater than or equal to 4 mm and less than or equal to 8 mm. That is, the size range of the first bending area 101a along the second direction Y may be 4 mm-8 mm, so that the distance between the first boundary 1011 and the second boundary 1012 may be avoided to be too small, and the stress of the foldable display panel 100 of the first bending area 101a when bending is relatively small, so as to reduce the bending stress exerted to each film layer, and avoid the distance between the first boundary 1011 and the second boundary 1012 to be too large, which would otherwise be not conducive to the thinness of the foldable display panel 100 when in a folded state.

For example, a distance between the first boundary 1011 and the second boundary 1012 may be 4 mm, 5 mm, 6 mm, 7 mm, 8 mm or any value between 4 mm and 8 mm.

Referring to FIG. 1, the two non-bending areas 100d may include a first non-bending area 101d and a second non-bending area 102d, and the first bending area 101a is located between the first non-bending area 101d and the second non-bending area 102d. The foldable display panel 100 located in the first bending area 101a may be bent and flattened, thereby realizing the folding and flattening of the foldable display panel 100.

It should be noted that the foldable display panel 100 may include a flattened state, a folded state, and an intermediate state therebetween, and a state in which the foldable display panel 100 is located is also a state in which the foldable display device is located.

As shown in FIG. 1, the flattened state refers to a state in which the various parts of the foldable display panel 100 are approximately in the same plane. At this time, the first non-bending area 101d, the second non-bending area 102d, and the first bending area 101a are approximately in the same plane, and an included angle between the first non-bending area 101d and the second non-bending area 102d is approximately 180 degree. In the flattened state, the display area of the foldable display panel 100 is relatively large to ensure a better user experience.

The folded state means that the first bending area 101a of the foldable display panel 100 is bent, and the foldable display panels 100 of the first non-bending area 101d and the second non-bending area 102d at least partially overlap in a thickness direction of the foldable display panel 100, and an included angle between the first non-bending area 101d and the second non-bending area 102d is approximately 0 degree. In the folded state, the foldable display panel 100 and the foldable display device having the foldable display panel 100 are small in volume, which is convenient for the storage and carrying of the foldable display device.

For example, the foldable display panel 100 may be bent in a teardrop shape, and a distance between the foldable display panels 100 of the two non-bending areas 100d is relatively close, which can reduce the entry of external dust into the foldable display panels 100 of the two non-bending areas 100d, thereby protecting the foldable display panel 100.

In some embodiments, the first bending area 101a may include a first display area 101b and a first non-display area 101c arranged along the first direction X, and the first non-display area 101c may be located on at least one side of the first display area 101b along the first direction X.

In some embodiments, referring to FIG. 1, each non-bending area 100d may include a second display area 102b and a second non-display area 102c located outside the second display area 102b, for example, the second non-display area 102c may be located on at least one side of the second display area 102b along the first direction X, and the second non-display area 102c may also be located on one side of the second display area 102b away from the first display area 101b. The second display area 102b and the first display area 101b may be connected with each other, and the second non-display area 102c and the first non-display area 101c may be connected with each other.

Herein, all the first non-display areas 101c and all the second non-display areas 102c jointly form a non-display area of the foldable display panel 100, and all the first display areas 101b and all the second display areas 102b jointly form a display area of the foldable display panel 100. The non-display area may be arranged around at least part of periphery of the display area.

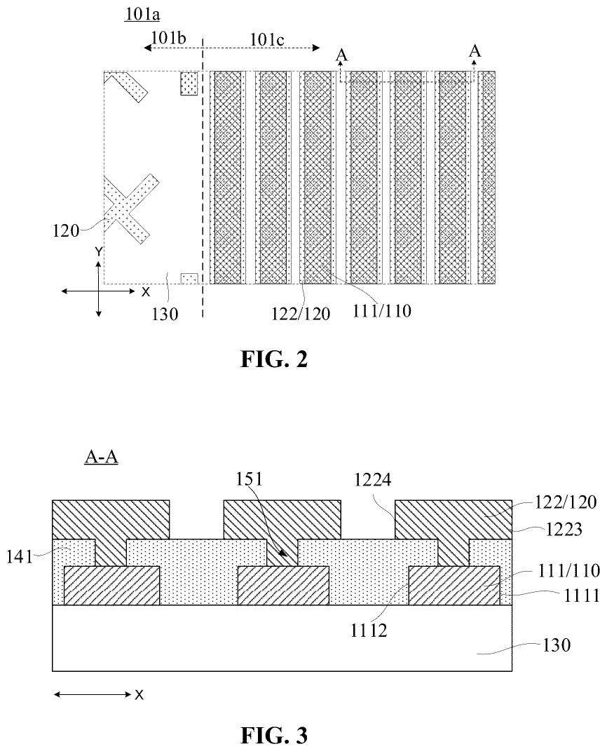

Exemplarily, the display area may include a plurality of opening areas and non-opening areas surrounding outside opening areas, and the foldable display panel 100 may also include a plurality of light-emitting elements and touch lead wires (the first touch lead wire 110 and/or the second touch lead wire 120 in FIG. 2), the light-emitting element is arranged corresponding to the opening area, and the light-emitting element is at least partially located in the corresponding opening area. The touch lead wire may be located in the non-opening area, so as to avoid the touch lead wire from affecting the light output of the light-emitting element.

In some embodiments, referring to FIG. 1, the foldable display panel 100 may include a second bending area 102a located on a side of the first non-bending area 101d away from the first bending area 101a. By bending the foldable display panel 100 in the second bending area 102a, a flexible circuit board (not shown in the figure) connected to the foldable display panel 100 can be disposed on a backlight surface of the foldable display panel 100. In this way, a border width of the foldable display device can be reduced.

In some embodiments, referring to FIG. 1, in the first non-bending area 101d, the second non-display area 102c may include a first sub-non-display area 1021c and a second sub-non-display area 1022c, the first sub-non-display area 1021c being located on a side of the second display area 102b away from the first bending area 101a, and the second sub-non-display area 1022c being located on opposite sides of the second display area 102b along the first direction X.

In some embodiments, referring to FIG. 3, the foldable display panel 100 may include a display substrate 130 and a touch lead wire (a first touch lead wire 110 and/or a second touch lead wire 120) located on one side of the display substrate 130, and the display substrate 130 may provide support for the remaining structural layers that are subsequently arranged. The touch lead wire may be used to implement a touch function.

Exemplarily, referring to FIG. 3, the touch lead wire may include a first touch lead wire 110 and a second touch lead wire 120 which are arranged in a stacked manner, and the second touch lead wire 120 may be located on a side of the first touch lead wire 110 away from the display substrate 130.

Exemplarily, a thickness of the second touch lead wire 120 along a thickness direction of the display substrate 130 may be greater than a thickness of the first touch lead wire 110 along the thickness direction of the display substrate 130, so that the thickness of the second touch lead wire 120 is larger and the second touch lead wire 120 is not prone to fracture when being folded. In addition, the thickness of the first touch lead wire 110 is smaller, which is conducive to the thinness of the foldable display panel 100.

In some embodiments, referring to FIG. 3, the foldable display device may be an inner folding display device, that is, when the foldable display device is in a folded state, the folded touch lead wire is located on an inner side of the display substrate 130. At this time, a surface of the display substrate 130 in the first non-bending area 101d facing one side of the touch lead wire faces towards a surface of the display substrate 130 in the second non-bending area 102d facing one side of the touch lead wire. At this time, the foldable display panel 100 is an inner folding display panel.

In some embodiments, the foldable display device may be an outer folding display device, that is, when the foldable display device is in a folded state, the folded touch lead wire is located on the outside of the display substrate 130, and the foldable display panel 100 can realize the display function in the folded state to meet the needs of different display scenes. At this time, the surface of the display substrate 130 in the first non-bending area 101d away from one side of the touch lead wire faces away from the surface of the display substrate 130 in the second non-bending area 102d away from one side of the touch lead wire. At this time, the foldable display panel 100 is an outer folding display panel.

The embodiment of the present application is described by taking an example that the foldable display panel 100 is an inner folding display panel.

The following is a specific description of each film layer of the foldable display panel 100 provided in the embodiments of the present application.

In some embodiments, referring to FIG. 11, a first insulating layer 141 (for example, an inorganic material with low cost) may be arranged between the first touch lead wire 110 and the second touch lead wire 120, and the first insulating layer 141 may be used to electrically isolate the first touch lead wire 110 from the second touch lead wire 120. A second insulating layer 142 may be provided on a side of the first touch lead wire 110 or the second touch lead wire 120 that is farther away from the display substrate 130 and faces away from the display substrate 130. The second insulating layer 142 may be used to protect the touch lead wire and may also play a role in flattening (for example, an organic material).

Referring to FIG. 1 and FIG. 2, in at least part of the first bending area 101a (for example, the first non-display area 101c and/or part of the first display area 101b), an orthographic projection of the first touch lead wire 110 on the display substrate 130 may be located within an orthographic projection of the second touch lead wire 120 on the display substrate 130. In this way, in at least part of the first bending area 101a, a size of the second touch lead wire 120 is larger than a size of the first touch lead wire 110, and an edge of the orthographic projection of the second touch lead wire 120 on the display substrate 130 is located outside the orthographic projection of the first touch lead wire 110 on the display substrate 130, so that the edge of the second touch lead wire 120 and the first touch lead wire 110 are not arranged directly opposite each other in the thickness direction of the display substrate 130. After the foldable display panel 100 is folded, in at least part of the first bending area 101a, the edge of the second touch lead wire 120 may not generate a force on the first touch lead wire 110, and the force exerted by the non-edge part of the second touch lead wire 120 to the first touch lead wire 110 is relatively uniform (the force is a surface force), thereby alleviating the fracture condition of the first touch lead wire 110.

The touch lead wire of the first non-display area 101c provided in the embodiment of the present application is described below.

In some embodiments, referring to FIG. 2 and FIG. 3, in the first non-display area 101c, the first touch lead wire 110 may include a first portion section 111, the second touch lead wire 120 may include a second portion section 122, the first portion section 111 and the second portion section 122 may both extend along the second direction Y, and the first portion section 111 and the second portion section 122 may be electrically connected, thereby realizing the parallel connection of the first portion section 111 and the second portion section 122, so as to reduce the resistance of the touch lead wire at the first portion section 111 and the second portion section 122, and improve the signal transmission stability of the touch lead wire at the first portion section 111 and the second portion section 122.

Exemplarily, referring to FIG. 2 and FIG. 3, a width of the first portion section 111 along the first direction X is smaller than a width of the second portion section 122 along the first direction X, and an orthographic projection of the first portion section 111 on the display substrate 130 is located within an orthographic projection of the second portion section 122 on the display substrate 130. In this way, a width of the second portion section 122 in the first direction X is greater than a width of the first portion section 111 in the first direction X, so that edges of the second portion section 122 on both sides along the first direction X and the first portion section 111 are not arranged directly opposite each other in the thickness direction of the display substrate 130, after the foldable display panel 100 is folded, the edges of the second portion section 122 on both sides along the first direction X may not generate a force on the first portion section 111, thereby alleviating the fracture condition of the first portion section 111. The principle has been explained and will not be repeated.

Exemplarily, referring to FIG. 3, the first portion section 111 may have a first side 1111 and a second side 1112 arranged oppositely along the first direction X, and the second portion section 122 may have a third side 1223 and a fourth side 1224 arranged oppositely along the first direction X. The first side 1111 and the third side 1223 are close to each other, and the second side 1112 and the fourth side 1224 are close to each other. An orthographic projection of the first side 1111 on the display substrate 130 has a first distance from an orthographic projection of the third side 1223 on the display substrate 130, and an orthographic projection of the second side 1112 on the display substrate 130 has a second distance from an orthographic projection of the fourth side 1224 on the display substrate 130.

For example, the first distance may be greater than or equal to 10 μm and less than or equal to 20 μm, so that the first distance can be prevented from being too small, so that the edges of the second portion section 122 on both sides along the first direction X and the first portion section 111 can be ensured not to be arranged directly opposite each other in the thickness direction of the display substrate 130 under the premise of the existence of the manufacturing process error, so as to better alleviate the fracture condition of the first portion section 111, in addition, the first distance can be avoided to be too large, thereby improving the layout density of the touch lead wire.

For example, the first distance may be greater than or equal to 13 μm and less than or equal to 18 μm, so as to better alleviate the fracture condition of the first portion section 111. In addition, the layout density of the touch lead wire can be better improved.

For example, the first distance may be 10 μm, 12 μm, 13 μm, 15 μm, 18 μm, 20 μm or any value between 10 μm-20 μm.

For example, the second distance may be greater than or equal to 10 μm and less than or equal to 20 μm, so as to alleviate the fracture condition of the first portion section 111. In addition, the layout density of the touch lead wire can be improved. The principle has been explained and will not be repeated.

For example, the second distance can be greater than or equal to 13 μm and less than or equal to 18 μm, so that the fracture condition of the first portion section 111 can be better alleviated. In addition, the layout density of the touch lead wire can be better improved.

For example, the second distance may be 10 μm, 12 μm, 13 μm, 15 μm, 18 μm, 20 μm or any value between 10 μm-20 μm.

Exemplarily, the first distance may be equal to the second distance, which is conducive to the uniformity of the force exerted by the second portion section 122 to the first portion section 111. In other examples, the first distance may not be equal to the second distance, thereby reducing the difficulty of preparation.

The touch lead wire of the non-bending area 100d provided in the embodiment of the present application is described below.

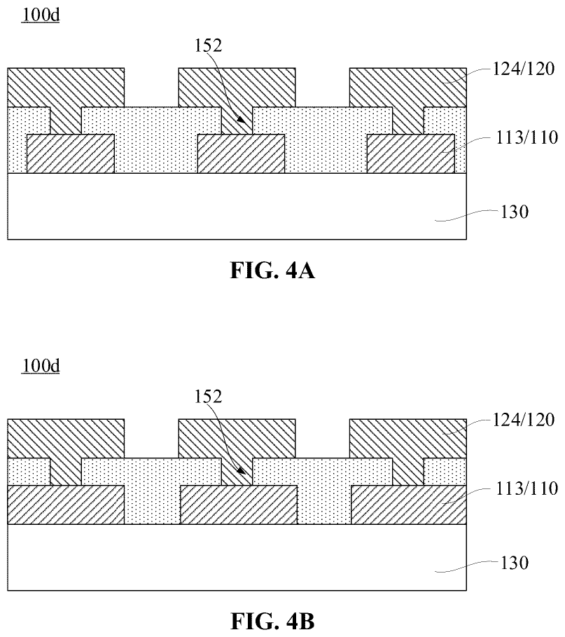

In some embodiments, referring to FIGS. 4a and 4b, in the non-bending area 100d,the first touch lead wire 110 may include a third portion section 113, and the second touch lead wire 120 may include a fourth portion section 124. For example, the extension directions of the third portion section 113 and the fourth portion section 124 may be the same. For example, the third portion section 113 and the fourth portion section 124 may both obliquely intersect with the first direction X. For another example, the third portion section 113 and the fourth portion section 124 may both be parallel to the first direction X or the second direction Y.

For example, referring to FIG. 4A, a width of the third portion section 113 along the extension direction perpendicular to the third portion section 113 is smaller than a width of the fourth portion section 124 along the extension direction perpendicular to the third portion section 113, and an orthographic projection of the third portion section 113 on the display substrate 130 may be located within an orthographic projection of the fourth portion section 124 on the display substrate 130, so that the width of the fourth portion section 124 is relatively large, which is conducive to realizing the electrical connection between the third portion section 113 and the fourth portion section 124. For example, the third portion section 113 and the fourth portion section 124 can be connected with each other through the second via 152. In addition, the width of the fourth portion section 124 is relatively large, and the fourth portion section 124 can better shield the third portion section 113, thereby better alleviating the reflection of the third segment 113 on the ambient light.

For another example, referring to FIG. 4B, a width of the third portion section 113 along the extension direction perpendicular to the third portion section 113 may be equal to a width of the fourth portion section 124 along the extension direction perpendicular to the third portion section 113, and an orthographic projection of the third portion section 113 on the display substrate 130 and an orthographic projection of the fourth portion section 124 on the display substrate 130 may overlap, thereby facilitating the reduction of the layout space of the foldable display panel 100 occupied by the third portion section 113 and the fourth portion section 124, and facilitating the improvement of the aperture ratio of the foldable display panel 100.

The touch lead wire of the first display area 101b provided in the embodiment of the present application is described below.

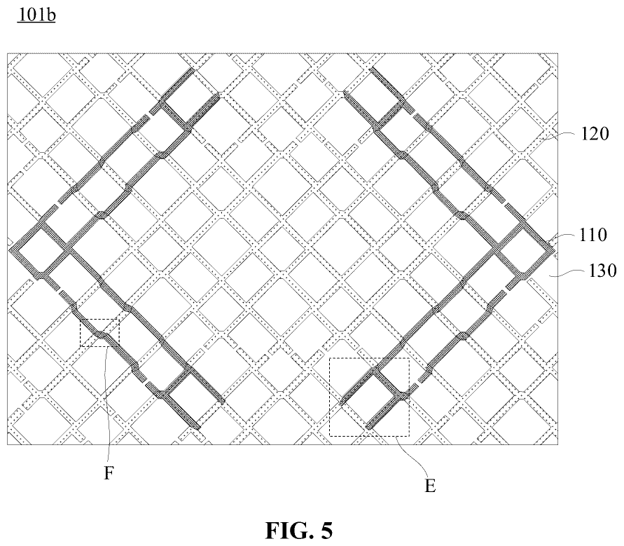

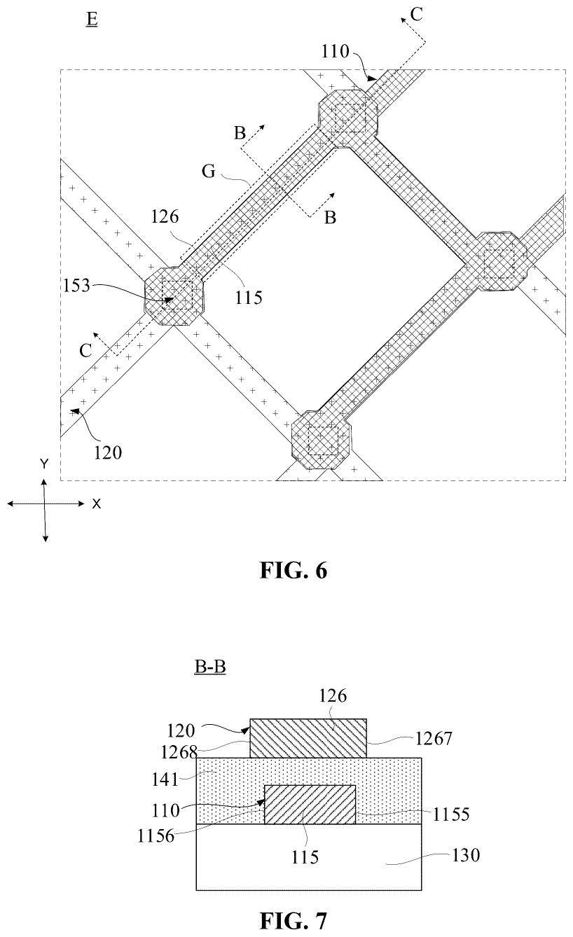

In some embodiments, referring to FIG. 5 and FIG. 6, in the first display area 101b, the first touch lead wire 110 may include a fifth portion section 115, and the second touch lead wire 120 may include a sixth portion section 126, and the extension directions of the fifth portion section 115 and the sixth portion section 126 may be the same. For example, the fifth portion section 115 and the sixth portion section 126 may both obliquely intersect with the first direction X. For another example, the fifth portion section 115 and the sixth portion section 126 are both parallel to the first direction X or the second direction Y.

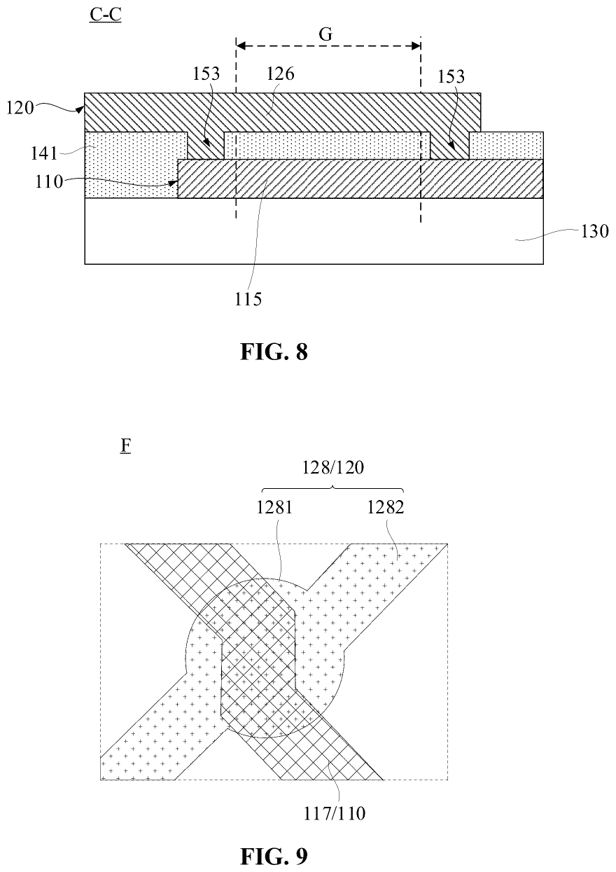

Exemplarily, referring to FIG. 7 and FIG. 8, the fifth portion section and the sixth portion section 126 can be connected with each other through a third via 153.

Exemplarily, referring to FIG. 6 and FIG. 7, a width of the fifth portion section 115 along the extension direction perpendicular to the fifth portion section 115 may be smaller than a width of the sixth portion section 126 along the extension direction perpendicular to the fifth portion section 115, and an orthographic projection of the fifth portion section 115 on the display substrate 130 is located within an orthographic projection of the sixth portion section 126 on the display substrate 130. The fifth portion section 115 and the sixth portion section 126 may both be located in an overlapping area G (FIG. 6). In this way, edges of the sixth portion section 126 on both sides along a width direction and the fifth portion section 115 are not arranged directly opposite each other in the thickness direction of the display substrate 130. After the foldable display panel 100 is folded, the edges of the sixth portion section 126 on both sides along the width direction may not generate a force on the fifth portion section 115, thereby alleviating the fracture condition of the fifth portion section 115. The principle has been explained and will not be repeated.

Exemplarily, referring to FIG. 6 and FIG. 7, along the extension direction perpendicular to the fifth portion section 115, the fifth portion section 115 may have a fifth side 1155 and a sixth side 1156 arranged opposite to each other, and the sixth portion section 126 may have a seventh side 1267 and an eighth side 1268 arranged opposite to each other. The fifth side 1155 and the seventh side 1267 are close to each other, and the sixth side 1156 and the eighth side 1268 are close to each other. An orthographic projection of the fifth side 1155 on the display substrate 130 may have a third distance from an orthographic projection of the seventh side 1267 on the display substrate 130, and an orthographic projection of the sixth side 1156 on the display substrate 130 may have a fourth distance from an orthographic projection of the eighth side 1268 on the display substrate 130.

For example, the third distance may be greater than or equal to 0.5 μm and less than or equal to 12 μm, so that the third distance can be prevented from being too small, and the edges of the sixth portion section 126 on both sides in the width direction and the fifth portion section 115 can be ensured not to be arranged directly opposite each other along the thickness direction of the display substrate 130 under the premise of the existence of the manufacturing process error, which can better alleviate the fracture condition of the fifth portion section 115. In addition, the third distance can be prevented from being too large, which can be conductive to improving the aperture ratio of the foldable display panel 100.

For example, the third distance may be greater than or equal to 0.7 μm and less than or equal to 10 μm, so that the fracture condition of the fifth portion section 115 can be better alleviated. In addition, the aperture ratio of the foldable display panel 100 can be better improved.

For example, the third distance may be 0.5 μm, 1 μm, 2 μm, 5 μm, 10 μm, 12 μm or any value between 0.5 μm and 12 μm.

For example, the fourth distance may be greater than or equal to 0.5 μm and less than or equal to 12 μm, so that the fracture condition of the fifth portion section 115 can be alleviated. In addition, the aperture ratio of the foldable display panel 100 can be improved. The principle has been explained and will not be repeated.

For example, the fourth distance may be greater than or equal to 0.7 μm and less than or equal to 10 μm, so that the fracture condition of the fifth portion section 115 can be better alleviated. In addition, the aperture ratio of the foldable display panel 100 can be better improved.

For example, the fourth distance may be 0.5 μm, 1 μm, 2 μm, 5 μm, 10 μm, 12 μm or any value between 0.5 μm and 12 μm.

Exemplarily, the third distance may be equal to the fourth distance, which is conductive to the uniformity of the force exerted by the sixth portion section 126 to the fifth portion section 115 after the foldable display panel 100 is folded. In other examples, the third distance may not be equal to the fourth distance, so that the difficulty of preparation can be reduced.

In some embodiments, referring to FIG. 5 and FIG. 9, in the first display area 101 b, the first touch lead wire 110 may include a seventh portion section 117, the second touch lead wire 120 may include an eighth portion section 128, an extension direction of the seventh portion section 117 and an extension direction of the eighth portion section 128 may be different, and the seventh portion section 117 and the eighth portion section 128 may be staggered. For example, the eighth portion section 128 may include a first sub-portion section 1281 and a second sub-portion section 1282 connected to each other. A width of the first sub-portion section 1281 along the extension direction perpendicular to the eighth portion section 128 may be greater than a width of the second sub-portion section 1282 along the extension direction perpendicular to the eighth portion section 128, so that the width of the second sub-portion section 1282 is smaller, which is conducive to improving the aperture ratio. In addition, an orthographic projection of the seventh portion section 117 on the display substrate 130 and an orthographic projection of the eighth portion section 128 on the display substrate 130 intersect with an orthographic projection of the first sub-portion section 1281 on the display substrate 130. Since a width of the first sub-portion section 1281 is larger, an area of the first sub-portion section 1281 is larger. After the foldable display panel 100 is folded, the force of the first sub-portion section 1281 on the seventh portion section 117 can be dispersed more on the first insulating layer 141, so that the stress on the seventh portion section 117 can be alleviated to alleviate the fracture phenomenon of the seventh portion section 117. In addition, the first sub-portion section 1281 and the seventh portion section 117 have a large facing area along the thickness direction of the display substrate 130, so that the force exerted by the first sub-portion section 1281 on the seventh portion section 117 can be more dispersed and uniform, thereby further alleviating the fracture phenomenon of the seventh portion section 117.

Exemplarily, the first sub-portion section 1281 is a circular structure or a polygonal structure, which is conducive to better expanding the area of the first sub-portion section 1281.

The touch lead wire of the first sub-non-display area 1021c provided in the embodiment of the present application is described below.

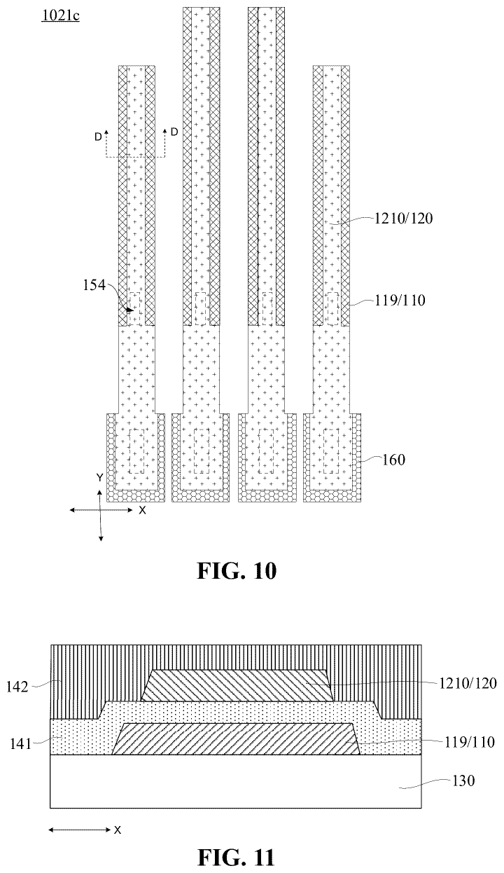

In some embodiments, referring to FIG. 10 and FIG. 11, in the first sub-non-display area 1021c, the first touch lead wire 110 may include a ninth portion section 119, and the second touch lead wire 120 may include a tenth portion section 1210. The tenth portion section 1210 may be closer to the light-emitting side of the foldable display panel 100 than the ninth portion section 119. The tenth portion section 1210 is located in an upper layer of FIG. 11, and the ninth portion section 119 is located in a lower layer of FIG. 11. The ninth portion section 119 and the tenth portion section 1210 both extend along the second direction Y. For example, the ninth portion section 119 and the tenth portion section 1210 can be electrically connected through the fourth via 154, so that the resistance of the touch lead wire at the ninth portion section 119 and the tenth portion section 1210 can be reduced.

Exemplarily, the display panel 100 may be provided with a conductive member 160 that can be used to switch the touch lead wires to other layers. For example, the conductive member 160 may be located in the first sub-non-display area 1021c.

It should be noted that ink can be provided in the non-display area of the foldable display panel 100. If the ink in the first sub-non-display area 1021c does not fully cover the first sub-non-display area 1021c due to the existence of process errors, one end of the first sub-non-display area 1021c close to the second display area 102 may not be covered by ink.

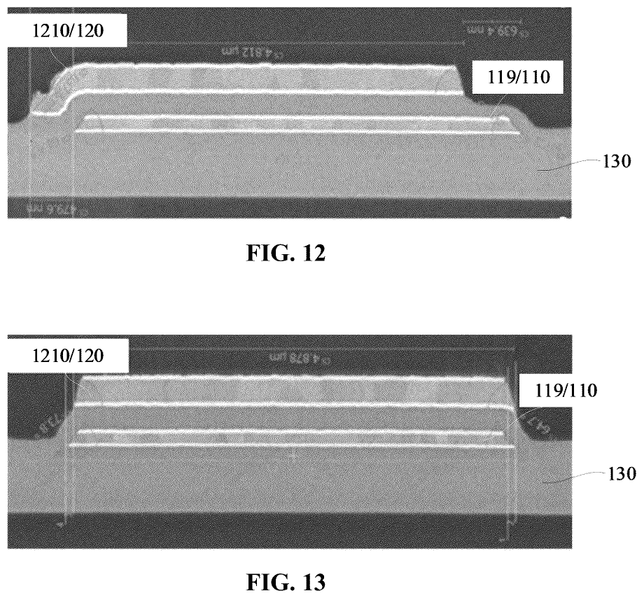

Exemplarily, the touch lead wire in the display area can be connected to the touch chip through the touch lead wire in the non-display area. The touch lead wires in the non-display area on both sides of the display area along the first direction X can all extend into the first sub-non-display area 1021c, and extend into the second bending area 102a through the first sub-non-display area 1021c. Therefore, the number of touch lead wires in the first sub-non-display area 1021c is relatively large. If one end of the first sub-non-display area 1021c close to the second display area 102 is not covered by ink, a relatively large number of touch lead wires are not covered by the ink layer and reflect ambient light. FIG. 12 is a cross-sectional scanning electron microscope diagram when widths of the ninth portion section 119 and the tenth portion section 1210 are equal. Since the widths of the ninth portion section 119 and the tenth portion section 1210 are equal, it is easy to cause the ninth portion section 119 and the tenth portion section 1210 to not completely overlap along the thickness direction of the display substrate 130, thereby causing the tenth portion section 1210 facing the edge of the ninth portion section 119 to sink, resulting in an increase in the metal reflective area of the side edge of the tenth portion section 1210 in the area not covered by ink, and resulting in the problem of reflective white spot visual effect.

Therefore, referring to FIG. 10 and FIG. 11, an orthographic projection of a end of the tenth portion section 1210 close to the second display area 102b (FIG. 1) on the display substrate 130 can be arranged to be located within an orthographic projection of a end of the ninth portion section 119 close to the second display area 102b on the display substrate 130. A width of the end of the ninth portion section 119 close to the second display area 102b along the first direction X is greater than a width of the end of the tenth portion section 1210 close to the second display area 102b along the first direction X, so that the tenth portion section 1210 may not face the edge of the ninth portion section 119 along the thickness direction of the display substrate 130, thereby alleviating the phenomenon of the tenth portion section 1210 sinking, and alleviating the problem of the reflective white spot visual effect. FIG. 13 is a cross-sectional scanning electron microscope diagram when the width of the ninth portion section 119 is greater than the width of the tenth portion section 1210. It can be seen that the tenth portion section 1210 has no sinking phenomenon.

In some embodiments, one of the first touch lead wire 110 and the second touch lead wire 120 is a bridge layer, and the other of the first touch lead wire 110 and the second touch lead wire 120 may be a touch function layer. The embodiments of the present application are described by taking an example that the first touch lead wire 110 is a bridge layer and the second touch lead wire 120 is a touch function layer.

Exemplarily, the touch function layer may include a plurality of first touch electrodes extending along the first direction X, and a plurality of second touch electrodes extending along the second direction Y, and the first touch electrodes and the second touch electrodes are interlaced (i.e., crossed). Each first touch electrode may include a plurality of first touch electrode blocks arranged along the first direction X, and the first touch electrode block may be a grid structure formed by the second touch lead wires 120 arranged in a cross pattern. Each second touch electrode may include a plurality of second touch electrode blocks arranged along the second direction Y, and the second touch electrode block may be in a grid structure formed by the second touch lead wires 120 arranged in a cross pattern. Since the touch electrode block (the first touch electrode block and the second touch electrode block) is in a grid structure, the touch electrode block in the grid structure may be located in the non-opening area so that the grid structure does not block the opening area, thereby reducing the influence of the touch lead wire on the display effect of the display area.

Exemplarily, the multiple touch electrode blocks of one of the first touch electrode and the second touch electrode can be connected by the second touch lead wire 120 to form an uninterrupted structure. The multiple touch electrode blocks of the other of the first touch electrode and the second touch electrode are disconnected and can be connected by a bridge formed by the first touch lead wire 110. The bridge may be located at an intersection position of the first touch electrode and the second touch electrode to avoid the first touch electrode and the second touch electrode from short-circuiting at the intersection position.

Exemplarily, one of the first touch electrode and the second touch electrode is a driving electrode, and the other of the first touch electrode and the second touch electrode is a sensing electrode (detection electrode).

Exemplarily, the material of at least one of the first touch lead wire 110 and the second touch lead wire 120 may include any one or more of metals such as titanium, silver, copper, aluminum, molybdenum, or alloys, or conductive oxides (such as indium tin oxide (ITO), indium zinc oxide (IZO), zinc oxide (ZnO), aluminum zinc oxide (AZO), zinc gallium oxide, titanium tantalum oxide, tin oxide, cadmium oxide, indium oxide.

The technical features of the above-mentioned embodiments can be combined arbitrarily. In order to make the description concise, all possible combinations of the technical features in the above-mentioned embodiments are not described. However, as long as there is no contradiction in the combination of these technical features, they should be considered to be within the scope of this specification.

The above-mentioned embodiments only express several implementation methods of the present application, and the description is relatively specific and detailed, but it cannot be understood as limiting the scope of the present disclosure. It should be pointed out that for those skilled in the art, several modifications and improvements can be made without departing from the concept of the present application, which all belong to the protection scope of the present application. Therefore, the scope of protection in the present disclosure should be based on the attached claims.

What is claimed is:

1. A foldable display panel, wherein the foldable display panel has a first bending area, and comprises a display substrate and a touch lead wire located on a side of the display substrate, the touch lead wire comprises a first touch lead wire and a second touch lead wire, the second touch lead wire being located on a side of the first touch lead wire away from the display substrate, a thickness of the second touch lead wire along a thickness direction of the display substrate being greater than a thickness of the first touch lead wire along the thickness direction of the display substrate;
in at least part of the first bending area, an orthographic projection of the first touch lead wire on the display substrate is located within an orthographic projection of the second touch lead wire on the display substrate.

2. The foldable display panel according to claim 1, wherein the first bending area comprises a first display area and a first non-display area arranged along a first direction, a non-bending area is provided on at least one side of the first bending area along a second direction, and the first direction intersecting with the second direction.

3. The foldable display panel according to claim 2, wherein in the first non-display area, the first touch lead wire comprises a first portion section, the second touch lead wire comprises a second portion section, the first portion section and the second portion section both extend along the second direction and are electrically connected;
a width of the first portion section along the first direction is smaller than a width of the second portion section along the first direction, and an orthographic projection of the first portion section on the display substrate is located within an orthographic projection of the second portion section on the display substrate.

4. The foldable display panel according to claim 3, wherein the first portion section has a first side and a second side arranged oppositely along the first direction, and the second portion section has a third side and a fourth side arranged oppositely along the first direction;
an orthographic projection of the first side on the display substrate has a first distance from an orthographic projection of the third side on the display substrate, and an orthographic projection of the second side on the display substrate has a second distance from an orthographic projection of the fourth side on the display substrate;
the first distance is greater than or equal to 10 μm and less than or equal to 20 μm;
and/or, the second distance is greater than or equal to 10 μm and less than or equal to 20 μm.

5. The foldable display panel according to claim 4, wherein the first distance is greater than or equal to 13 μm and less than or equal to 18 μm;
and/or, the second distance is greater than or equal to 13 μm and less than or equal to 18 μm.

6. The foldable display panel according to claim 4, wherein the first distance is equal to the second distance.

7. The foldable display panel according to claim 2, wherein the first bending area has a first boundary and a second boundary spaced apart along the second direction;
a distance between the first boundary and the second boundary is greater than or equal to 4 mm and less than or equal to 8 mm.

8. The foldable display panel according to claim 2, wherein in the non-bending area, the first touch lead wire further comprises a third portion section, the second touch lead wire further comprises a fourth portion section, and the third portion section and the fourth portion section have a same extension direction; and
a width of the third portion section along an extension direction perpendicular to the third portion section is less than a width of the fourth portion section along the extension direction perpendicular to the third portion section, and an orthographic projection of the third portion section on the display substrate is located within an orthographic projection of the fourth portion section on the display substrate.

9. The foldable display panel according to claim 2, wherein in the non-bending area, the first touch lead wire further comprises a third portion section, the second touch lead wire further comprises a fourth portion section, and the third portion section and the fourth portion section have a same extension direction;
a width of the third portion section along an extension direction perpendicular to the third portion section is equal to a width of the fourth portion section along the extension direction perpendicular to the third portion section, and an orthographic projection of the third portion section on the display substrate coincides with an orthographic projection of the fourth portion section on the display substrate.

10. The foldable display panel according to claim 2, wherein in the first display area, the first touch lead wire comprises a fifth portion section, the second touch lead wire comprises a sixth portion section, and the fifth portion section and the sixth portion section have a same extension direction;
a width of the fifth portion section along an extension direction perpendicular to the fifth portion section is smaller than a width of the sixth portion section along the extension direction perpendicular to the fifth portion section, and an orthographic projection of the fifth portion section on the display substrate is located within an orthographic projection of the sixth portion section on the display substrate.

11. The foldable display panel according to claim 10, wherein along the extension direction perpendicular to the fifth portion section, the fifth portion section has a fifth side and a sixth side arranged oppositely, and the sixth portion section has a seventh side and an eighth side arranged oppositely;
an orthographic projection of the fifth side on the display substrate has a third distance from an orthographic projection of the seventh side on the display substrate, and an orthographic projection of the sixth side on the display substrate has a fourth distance from an orthographic projection of the eighth side on the display substrate;
the third distance is greater than or equal to 0.5 μm and less than or equal to 12 μm;
and/or, the fourth distance is greater than or equal to 0.5 μm and less than or equal to 12 μm.

12. The foldable display panel according to claim 11, wherein the third distance is greater than or equal to 0.7 μm and less than or equal to 10 μm;
and/or, the fourth distance is greater than or equal to 0.7 μm and less than or equal to 10 μm.

13. The foldable display panel according to claim 11, wherein the third distance is equal to the fourth distance.

14. The foldable display panel according to claim 2, wherein in the first display area, the first touch lead wire comprises a seventh portion section, the second touch lead wire comprises an eighth portion section, an extension direction of the seventh portion section is different from an extension direction of the eighth portion section, and the eighth portion section has a first sub-portion section and a second sub-portion section connected with each other;
a width of the first sub-portion section along an extension direction perpendicular to the eighth portion section is greater than a width of the second sub-portion section along the extension direction perpendicular to the eighth portion section, and an orthographic projection of the seventh portion section on the display substrate and an orthographic projection of the eighth portion section on the display substrate intersect with an orthographic projection of the first sub-portion section on the display substrate.

15. The foldable display panel according to claim 14, wherein the first sub-portion section is a circular structure or a polygonal structure.

16. The foldable display panel according to claim 2, wherein the non-bending area comprises a first non-bending area, in the first non-bending area, the first non-bending area comprises a second display area and a second non-display area, the second non-display area is located outside part of the second display area connected to the first display area, and connected to the first non-display area;
the second non-display area comprises a first sub-non-display area located on a side of the second display area away from the first bending area; in the first sub-non-display area, the first touch lead wire comprises a ninth portion section, the second touch lead wire comprises a tenth portion section, the ninth portion section and the tenth portion section both extend along the second direction and are electrically connected;
an orthographic projection of one end of the tenth portion section close to the second display area on the display substrate is located within an orthographic projection of one end of the ninth portion section close to the second display area on the display substrate; and
a width of one end of the ninth portion section close to the second display area along the first direction is greater than a width of one end of the tenth portion section close to the second display area along the first direction.

17. The foldable display panel according to claim 3, wherein the first bending area has a first boundary and a second boundary spaced apart along the second direction;
a distance between the first boundary and the second boundary is greater than or equal to 4 mm and less than or equal to 8 mm.

18. The foldable display panel according to claim 3, wherein in the non-bending area, the first touch lead wire further comprises a third portion section, the second touch lead wire further comprises a fourth portion section, and the third portion section and the fourth portion section have a same extension direction; and
a width of the third portion section along an extension direction perpendicular to the third portion section is less than a width of the fourth portion section along the extension direction perpendicular to the third portion section, and an orthographic projection of the third portion section on the display substrate is located within an orthographic projection of the fourth portion section on the display substrate.

19. The foldable display panel according to claim 3, wherein in the non-bending area, the first touch lead wire further comprises a third portion section, the second touch lead wire further comprises a fourth portion section, and the third portion section and the fourth portion section have a same extension direction;
a width of the third portion section along an extension direction perpendicular to the third portion section is equal to a width of the fourth portion section along the extension direction perpendicular to the third portion section, and an orthographic projection of the third portion section on the display substrate coincides with an orthographic projection of the fourth portion section on the display substrate.

20. A foldable display device, comprising a foldable display panel, wherein the foldable display panel has a first bending area, and comprises a display substrate and a touch lead wire located on a side of the display substrate, the touch lead wire comprises a first touch lead wire and a second touch lead wire, the second touch lead wire being located on a side of the first touch lead wire away from the display substrate, a thickness of the second touch lead wire along a thickness direction of the display substrate being greater than a thickness of the first touch lead wire along the thickness direction of the display substrate;
in at least part of the first bending area, an orthographic projection of the first touch lead wire on the display substrate is located within an orthographic projection of the second touch lead wire on the display substrate.
